(19) United States
(12) Patent Application Publication
(10) Pub. No.: US 2006/0197689 A1
(43) Pub. Date: Sep. 7, 2006

(54) Parallelized binary arithmetic coding

(75) Inventors: Jian-Hung Lin, St. Paul, MN (US); Keshab K. Parhi, Maple Grove, MN (US)

Correspondence Address: SHUMAKER & SIEFFERT, P. A., 8425 SEASONS PARKWAY, SUITE 105, ST. PAUL, MN, 55125, US

(73) Assignee: Regents of the University of Minnesota, Minneapolis, MN (US)

(21) Appl. No.: 11/367,041

(22) Filed: Mar. 2, 2006

Related U.S. Application Data
(60) Provisional application No. 60/658,202, filed on Mar. 2, 2005.

(51) Int. Cl. H03M 7/34

(52) U.S. Cl. 341/51

(57) ABSTRACT

The invention is directed to techniques of parallelizing binary arithmetic coding. Two exemplary parallelized binary arithmetic coding systems are presented. One parallelized binary arithmetic coding system utilizes linear approximation and a constant probability of a less probable symbol. A second parallelized binary arithmetic coding system utilizes a parallelized table lookup technique. Both parallelized binary arithmetic coding systems may have increased throughput as compared to non-parallelized arithmetic coders.

This application claims the benefit of U.S. Provisional Application No. 60/658,202, filed Mar. 2, 2005, the entire content of which is incorporated herein by reference.

### TECHNICAL FIELD

The invention relates to data compression, and, in particular, to arithmetic coding.

### BACKGROUND

Binary arithmetic coding is a lossless data compression technique based on a statistical model. Binary arithmetic coding is a popular because of its high speed, simplicity, and lack of multiplication. For these reasons, binary arithmetic coding is currently implemented in the Joint Photographic Experts Group (JPEG) codec, the Motion Pictures Experts Group (MPEG) codec, and many other applications.

To encode a string of bits, a binary arithmetic encoder performs the following recursive operations:
Ci+1=Ci+Si(k)Ai,
Ai+1=Ai*Pi(k), and

normalize.

where A is the width of an interval, C is the based value of the interval, Pᵢ(k) is the probability of a symbol k following a certain string, and Sᵢ(k) is the cumulative probability of symbol k. Therefore, S(k)=ΣP(j) for j=1 to k−1.

To decode a string of bits, a binary arithmetic decoder reverses the encoding operation:
Max{Si(k)Ai}s.t.Ci+1=Ci−Si(k)Ai≧0,
Ai+1=Ai*Pi(k), and

normalize.

### SUMMARY

In general, techniques are described to parallelize binary arithmetic encoding. In particular, the invention is directed to techniques for precisely encoding and decoding multiple binary symbols in a fixed number of clock cycles. By precisely encoding and decoding multiple binary symbols in a fixed number of clock cycles, the binary arithmetic coding system of this invention may significantly increase throughput.

For example, two exemplary parallelized binary arithmetic coding systems are described. One parallelized binary arithmetic coding system uses linear approximation and simplifies the hardware by assuming that the probability of encoding or decoding a less probable symbol is almost the same while performing the encoding and decoding. Another parallelized binary arithmetic coding system applies a table lookup technique and achieves parallelism with a parallelized probability model.

In one embodiment, the invention is directed to a method that comprises receiving a stream of binary data symbols. The method also comprises applying a parallel binary arithmetic coding scheme to a set of the data symbols to simultaneously encode the set of data symbols. The set of data symbols includes more probable binary symbols and less probable binary symbols.

In another embodiment, the invention is directed to a computer-readable medium comprising instructions. The instructions cause a programmable processor to receive a stream of binary data symbols apply a parallel binary arithmetic coding scheme to a set of the data symbols to simultaneously encode the set of data symbols. The set of data symbols includes more probable binary symbols and less probable binary symbols.

In another embodiment, the invention is directed to an electronic device comprising an encoder to encode a set of data symbols in a stream of binary data symbols. The encoder applies a parallel binary arithmetic coding scheme to encode all of the data symbols of the set of binary data symbols in parallel and the set of data symbols includes more probable binary symbols and less probable binary symbols.

In another embodiment, the invention is directed to an electronic device comprising a decoder to decode a set of data symbols in a stream of binary data symbols. The decoder applies a parallel binary arithmetic coding scheme to decode all of the data symbols of the set of binary data symbols in parallel and the set of data symbols includes more probable binary symbols and less probable binary symbols.

In another embodiment, the invention is directed to a system comprising a first communication device that comprises an encoder to encode a set of data symbols in a stream of binary data symbols. The encoder applies a parallel binary arithmetic coding scheme to encode all of the data symbols of the set of binary data symbols in parallel and the set of data symbols includes more probable binary symbols and less probable binary symbols. The system also comprises a second communication device that comprises a decoder to decode the set of data symbols. The decoder applies the parallel binary arithmetic coding scheme to decode all of the data symbols of the set of binary data symbols in parallel.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a block diagram of an exemplary high-speed network communication system.

FIG. 2 is a conceptual diagram illustrating probability ranges used in a binary arithmetic coding system that processes two symbols in parallel.

FIG. 3 is a block diagram illustrating an exemplary embodiment of a binary arithmetic encoder that uses two sets of linear approximations to estimate the probabilities of a two-symbol binary string.

FIG. 4 is a block diagram illustrating an exemplary embodiment of a decoding circuit for a 2-symbol QL-decoder that generates values of A.

FIG. 5 is a block diagram illustrating an exemplary embodiment of a decoding circuit for a 2-symbol QL-decoder that generates values of C.

FIG. 6 is a block diagram illustrating an exemplary embodiment of a 3-region QL-encoder.

FIG. 7 is a block diagram illustrating an exemplary embodiment of a decoding circuit that processes for three symbols in parallel.

FIG. 8 is a block diagram illustrating a binary arithmetic encoder that uses a table look-up mechanism to process two symbols in parallel.

FIG. 9 is a block diagram illustrating an exemplary interval locator that selects a set of C and A values given a value of Q.

FIG. 10 is a block diagram illustrating an exemplary data structure for use in a decoding interval locator.

FIG. 11 is a block diagram illustrating an exemplary embodiment of an interval locator based on the cumulative probability array data structure of FIG. 10.

### DETAILED DESCRIPTION

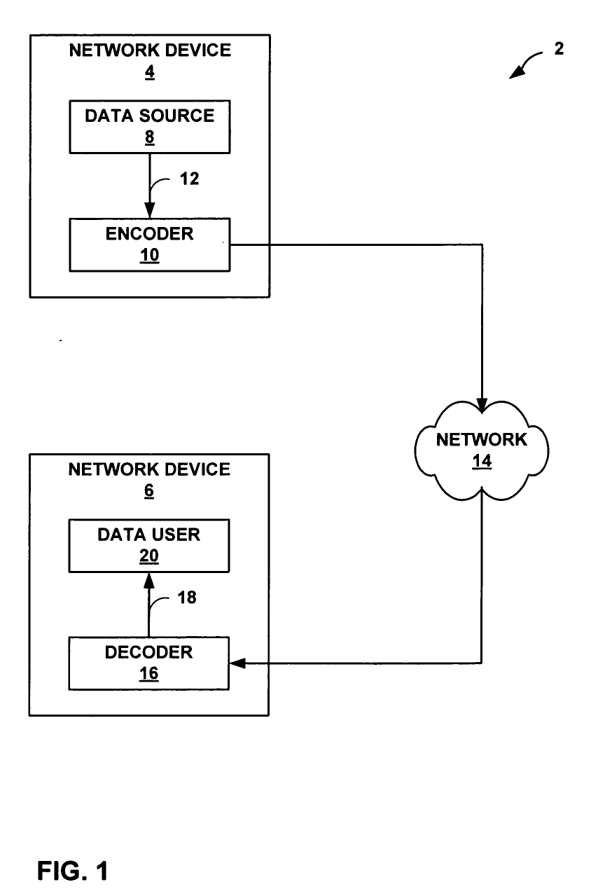

FIG. 1 is a block diagram of an exemplary high-speed network communication system 2. One example high-speed communication network is a 10 Gigabit Ethernet over copper network. Although the system will be described with respect to 10 Gigabit Ethernet over copper, it shall be understood that the present invention is not limited in this respect, and that the techniques described herein are not dependent upon the properties of the network. For example, communication system 2 could also be implemented within networks of various configurations utilizing one of many protocols without departing from the present invention.

In the example of FIG. 1, communication system 2 includes a first network device 4 and a second network device 6. Network device 4 comprises a data source 8 and an encoder 10. Data source 8 transmits outbound data 12 to encoder 10 for transmission via a network 14. For instance, outbound data 12 may comprise video data symbols such as Motion Picture Experts Group version 4 (MPEG-4) symbols. In addition outbound data 12 may comprise audio data symbols, text, or any other type of binary data. Outbound data 12 may take the form of a stream of symbols for transmission to receiver 14. Once network device 6 receives the encoded data, a decoder 16 in network device 6 decodes the data. Decoder 16 then transmits the resulting decoded data 18 to a data user 20. Data user 20 may be an application or service that uses decoded data 18.

Network device 4 may also include a decoder substantially similar to decoder 16. Network device 6 may also include an encoder substantially similar to encoder 10. In this way, the network devices 4 and 6 may achieve two way communication with each other or other network devices. Examples of network devices that may incorporate encoder 10 or decoder 16 include desktop computers, laptop computers, network enabled personal digital assistants (PDAs), digital televisions, network appliances, or generally any devices that code data using binary arithmetic coding techniques.

In one embodiment, encoder 10 is a parallel context-based binary arithmetic coder (CABAC) that does not utilize multiplication. As one example, encoder 10 may be an improvement of a multiplication free Q-coder proposed by IBM (referred to herein as the “IBM Q-coder”). Operation of the IBM Q-coder is further described by W. B. Pennebaker, J. L. Mitchell, G. G. Langdon, and R. B. Arps in “An Overview of the Basic Principles of the Q-Coder Adaptive Binary Arithmetic Coder,” IBM J. Res. Develop., Vol. 32, No. 6, pp. 717-726, 1988, hereby incorporated herein by reference in its entirety.

As another example, encoder 10 may be an improvement of the conventional CABAC used in H.264 video compression standard. Further details of the CABAC used in the H.264 standard are described by D. Marpe, H. Schwarz, and T. Wiegand, “Contect-based Adaptive Binary Arithmetic Coding in the H.264/AVC Video Compression Standard,” IEEE Transactions on Circuits and systems for video technology, Vol. 13, No. 7, pp. 620-636, July 2003, hereby incorporated herein by reference in its entirety.

The techniques of this invention may provide one or more advantages. For example, because embodiments of this invention process multiple symbols in parallel, arithmetic encoding and decoding may be accelerated. In addition, because embodiments of this invention process two or more probability regions in parallel, the embodiments may be more accurate.

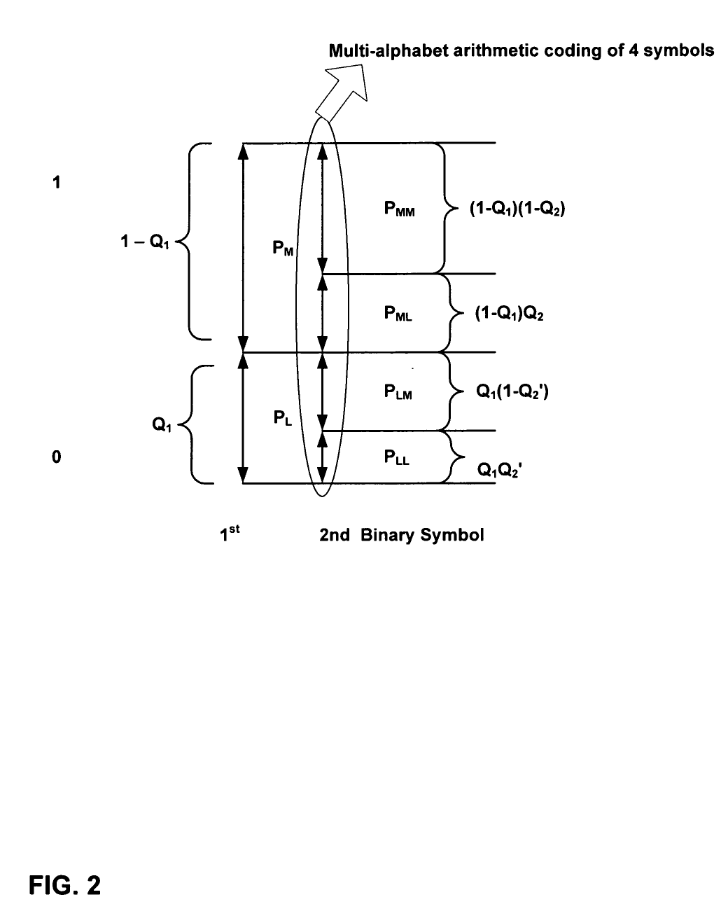

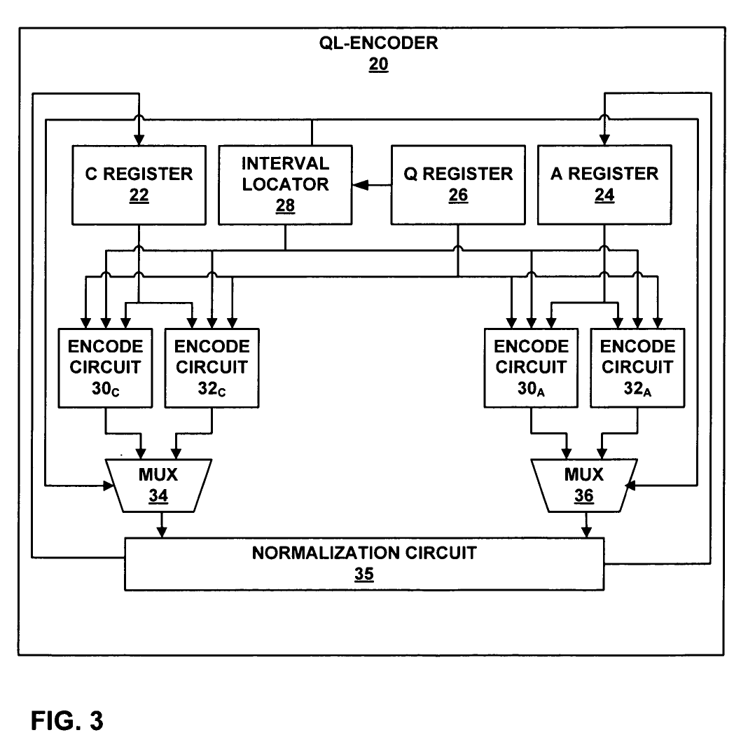

FIG. 2 is a conceptual diagram illustrating probability ranges used in a binary arithmetic coding system that processes two symbols in parallel. In FIG. 2, X and Y are numbers such that Y>X. A represents the distance between Y and X. For example, if Y equals 5 and X equals 2, A equals 3. Or in the case described in regards to FIG. 3, Y is presumed to equal 1, X equal 0, and hence A is equal to 1.

To encode a string of bits, encoder 10 (FIG. 1) collects occurrence information about the content of the bits. For instance, in the binary string 10110111 there are six Is and two 0s. Based on this occurrence information, encoder 10 characterizes 0 as the less probable symbol and 1 as the more probable symbol. In addition, encoder 10 may estimate that the probability of the next bit being a 0 is 2 out of 8 (i.e., ¼). The probability of the next bit being the less probable symbol (i.e., 0) is referred to herein as “Q”. Therefore, the probability of the next bit being the more probable symbol (i.e., 1) is equal to 1−Q.

In a binary arithmetic coding system that processes two symbols in parallel, encoder 10 may use the occurrence information to estimate the probability of the next two symbols simultaneously. In other words, encoder 10 may use the occurrence information to estimate the probability of receiving a particular binary string having two bits (i.e., 00, 01, 10, and 11). As encoder 10 encodes each additional symbol, the value of Q may change. For example, if encoder 10 encodes an additional more probable symbol, the value of Q may decrease to Q2. Alternatively, if encoder 10 encodes an additional less probable symbol, the value of Q may increase to Q2′. Thus, Q2≧Q≧Q2′.

Using elementary statistics, encoder 10 knows that the probability of receiving two less probable symbols in a row is Q*Q2′, the probability of receiving a less probable symbol and then a more probable symbol is Q*(1−Q2), the probability of receiving a more probable symbol and then a less probable symbol is (1−Q)*Q2, and the probability of receiving two more probable symbols in a row is (1−Q)*(1−Q2).

To encode a symbol, encoder 10 selects a value C within interval A. In particular, if encoder 10 is encoding a less probable symbol followed by another less probable symbol, encoder 10 selects a value C such that C is equal to X. Similarly, if encoder 10 is encoding a less probable symbol followed by a more probable symbol, encoder 10 selects a value of C such that C is equal to X+A*Q*Q2. If encoder 10 is encoding a more probable symbol followed by a less probable symbol, encoder 10 selects a value of C such that C is equal to X+A*Q*Q2+A*Q*(1−Q2′). If encoder 10 is encoding a more probable symbol followed by a more probable symbol, encoder 10 selects a value of C such that C is equal to X+A*Q*Q2+A*Q*(1−Q2′)+A*(1−Q)*(1−Q2).

To encode the next pair of symbols, encoder 10 sets A equal to the interval where C is. For example, if C is between X+A*Q*Q2+A*Q*(1−Q2′)+A*(1−Q)*(1−Q2) and Y, encoder 10 sets A equal to A*Q*Q2+A*Q*(1−Q2′)+A*(1−Q)*(1−Q2). Encoder 10 then uses the same process described in the paragraph above to select a new value of C using the new value of A. After encoding all or a portion of input 12, encoder 10 transmits this value of C to decoder 16.

Decoder 16 uses the same principles to translate the value of C into decoded message 18. For instance, if C is between X and X+A*Q*Q2, decoder 16 decodes a less probable symbol followed by another less probable symbol. To decode the next two symbols, decoder 16 sets A to A*Q*Q2 and sets C to the value of C minus A*Q*Q2.

Calculating Q*Q2, Q*(1−Q2′), (1−Q)*Q2 and (1−Q)*(1−Q2) may be computationally expensive. This is because the multiplication inherent in these calculations may require a considerable computation time. These computational costs become progressively greater as binary arithmetic coding system 2 looks at additional symbols simultaneously.

FIG. 3 is a block diagram illustrating an exemplary embodiment of a binary arithmetic encoder that uses two sets of linear approximations to estimate the probabilities of a two-symbol binary string. This binary arithmetic encoder is referred to herein as Q-Linear encoder (QL-encoder) 20 because the QL-encoder may apply a first-order linear approximations method to estimate Q, where Q is the probability of encoding or decoding a less probable symbol. QL-encoder 20 contains a C register 22 and an A register 24. C register 22 contains a coded representation of a bit string. A register 24 contains an interval. In addition, QL-encoder 20 contains two sets of encoding circuits 30 and 32. Encoding circuits 30 includes a circuit 30_{C} that generates values of C and circuit 30_{A} that generates values of A. Similarly, encoding circuits 32 includes a circuit 32_{C} that generates values for C and a circuit 32_{A} that generates values for A.

To eliminate a multiplication, QL-encoder 20 assumes that A equals 1. Moreover, QL-encoder 20 assumes that Q does not change within a block of input symbols. For these reasons, QL-encoder 20 may assume that the intervals P_{MM}=(1)*(1−Q)²=(1−Q)², P_{ML}=(1)(Q−Q²)=(Q−Q²), P_{LM}=(1)(Q−Q²)=(Q−Q²), and P_{LL}=(1)Q²=Q².

Encoding circuits 30 and 32 use linear approximations of P_{MM}, P_{ML}, P_{LM}, and P_{LL} to calculate values of C and A without multiplication. A linear approximation is a tangent line of a curve. When the tangent line is close to the curve, the tangent line is a reasonably accurate estimate of the curve.

Taylor's theorem may be applied to find tangent lines to P_{MM}=(1−Q)², P_{ML}=Q−Q², P_{LM}=Q−Q², and P_{LL}=Q². Taylor's Theorem states that f(a)=f(b)+f′(b)(a−b)+R₂ where R₂ is a remainder. A linear approximation of f(a) may be obtained by dropping R₂. Thus, f(a)≈f(b)+f′(b)(a−b) when a is close to b.

Applying this principle to P_{MM}, the linear approximation of P_{MM}(Q)=(1−Q)² is
P_{MM}(Q)≈(1−Q)² is −2(1−x)(Q−x)+(1−x)²
where x is a number close to Q. Note that the derivative of P_{MM}(Q) is P_{MM}′(Q)=−2(1−Q).

Based on symbol occurrence information, the variable x can be selected such that x is close to the expected value of Q. For example, the symbol occurrence information may indicate that the probability of receiving a less probable symbol is ¼. By substituting ¼ for x in the above equation, the linear approximation of P_{MM}(Q) where Q is near ¼ is derived:
P_{MM}(Q)≈(− 3/2)Q+ 15/16.
The multiplication of Q by (− 3/2) encoder 10 and decoder 16 replace the multiplication of (− 3/2) and Q with shift and add operations.

Similar linear approximations may be made concerning the equations for P_{ML}, P_{LM}, and P_{LL}. Thus when x is ¼,
P_{ML}(Q)=Q/2+ 1/16
P_{LM}(Q)=Q/2+ 1/16
P_{LL}(Q)=Q/2− 1/16≧0

Encoding circuits 30 and 32 calculate values of C and A using linear approximations where the expected values of Q are different. To illustrate why this may be necessary, note that each of P_{MM}(Q), P_{ML}(Q), P_{LM}(Q), and P_{LL}(Q) must be positive. This condition is satisfied if 0≦Q≦½, Q≦⅝, and Q≧⅛. Therefore, when the expected value of Q is ¼, this set of linear approximations is valid when Q is in the region of [⅛, ½]. Because the region [⅛, ½] does not cover the entire region [0, ½], a separate set of linear approximations may be calculated to cover the region [0, ⅛). For instance, a set of linear approximations where x= 1/16 covers the region [0, ⅛).

In addition, a QL-encoder (not illustrated) may calculate values of C and A using additional expected values of Q, even if calculating such values are not mathematically required to cover the region [0, ½]. This QL-encoder may achieve a higher compression ratio if there are more Q regions because this QL-encoder may generate values of C and A based on a more accurate expected value of Q.

Encoding circuits 30 and 32 use the linear approximations of intervals P_{MM}(Q), P_{ML}(Q), P_{LM}(Q), and P_{LL}(Q) to calculate values of C and A. For example, if encoding circuits 32 are associated with the region of Q where the expected value of Q is ¼, circuits 32_{C} and 32_{A} calculate each of the following values of C and A in parallel:
C←C+P_{LL}+P_{ML}+P_{ML}≈C+3Q/2+ 1/16
A←P_{MM}≈−3Q/2+ 15/16 (1)
C←C+P_{LL}+P_{LM}=C+Q
A+P_{ML}≈Q/2+ 1/16 (2)
C←C+P_{LL}=C+Q²≈C+Q/2− 1/16
A←P_{LM}≈Q/2+ 1/16 (3)
C←C+0=C
A←P_{LL}≈Q/2− 1/16 (4)

If encoding circuits 30 are associated with an expected value of Q equal to 1/16, circuits 30_{C} and 30_{A} calculate values of C and A based on linear equations where x= 1/16. Encoding circuits 30 calculate these values of C and A at the same time that encoding circuits 32 are calculating values of C and A listed above.

While encoding circuits 30 and 32 are calculating values of C and A, interval locator 28 examines the bit string to be encoded and selects which values of C and A to use. In particular, if the next two characters of the bit string are a more probable symbol (MPS) followed by another MPS, interval locator 28 selects set of values of C and A calculated with equations (1). If the next two characters of the bit string are MPS followed by a less probable symbol (LPS), interval locator 28 selects the set of values of C and A calculated with equations (2). If the next two characters of the bit string are LPS followed by a MPS, interval locator 28 selects the sets of values of C and A calculated with equations (3). Otherwise, if the next two characters of the bit string are LPS followed by a LPS, interval locator 28 selects the set of values of C and A calculated with equations (4).

At the same time, interval locator 28 uses the current value of Q in Q register 26 to determine whether to use the values of C and A generated by encoding circuits 30 or the values of C and A generated by encoding circuits 32. For instance, if the current value of Q in Q register 26 is in interval for [0, ⅛), interval locator 28 may choose the values of C and A generated by encoding circuits 28. Otherwise, if the current value of Q in Q register 26 is in the interval [⅛, ½], interval locator 28 chooses the values of C and A generated by encoding circuits 32. Interval locator 28 sends a signal to a multiplexer 34 to indicate whether interval locator 28 has chosen the value of C generated by encoding circuits 30 or encoding circuits 32. Interval locator 28 also sends a signal to a multiplexer 36 to indicate whether interval locator 28 has chosen the value of A generated by encoding circuits 30 or encoding circuits 32.

A two-symbol QL-decoder (not illustrated) may have similar components as QL-encoder 20. When QL-decoder receives an encoded version of data 12, the QL-decoder sets the encoded data as the value C in C register 22. Decoding circuits 30 and 32 of the QL-decoder then use linear approximations to calculate values of C and A for each expected value of Q in parallel. However, instead of adding the current values of C and A with the interval of Q as in QL-encoder, decoding circuits 30 and 32 of a QL-decoder generate new values of C and A by subtracting the interval of Q from the current values of C and A. For example, if decoding circuits 32 calculate intervals of Q for a string of two symbols when the expected value of Q is ¼, decoding circuit 32_{C} calculates the following values of C and decoding circuit 32_{A} calculates the following values of A in parallel:
C←C−3Q/2+ 1/16
A←−3Q/2+ 15/16 (1)
C←C−Q+⅛
A←−Q/2+ 1/16 (2)
C←C−Q/2+ 1/16
A←−Q/2+ 1/16 (3)
C←C−0=C
A←Q/2+ 1/16 (4)

While decoding circuits 30 and 32 of the QL-decoder are calculating values of C and A, interval locator 28 of the QL-decoder selects whether to use values of C and A generated by decoding circuits 30 or value of C and A generated by decoding circuits 32. For instance, if the current estimated value of Q in Q register 26 is near ¼, interval locator 28 of the QL-decoder may send signals to multiplexer 34 and multiplexer 36 to propagate values of C and A generated by circuits 32.

At the same time, interval locator 28 of the QL-decoder selects which values of C and A to use. In particular, interval locator 28 compares each of P_{LL}+P_{LM}+P_{ML}, P_{LL}+P_{LM}, P_{LL}, and 0 against the value of C in C register 22. For example, if interval locator 28 detects that the value of C in C register 22 is greater than P_{LL}+P_{LM}+P_{ML}=3Q/2− 1/16, interval locator 28 decodes a MPS followed by another MPS and sends a signal decoding circuit 32_{C} to propagate the values of C and A generated according to set (1). Otherwise, if interval locator 40 detects that the value of C in C register 22 is greater than P_{LL}+P_{LM}=(Q+⅛), interval locator 40 decodes a MPS followed by an LPS and sends a signal decoding circuit 32_{C} to propagate the values of C and A generated according to set (2). If the value of C in C register 22 is greater than P_{LL}+P_{LM}=(Q+⅛) and interval locator 40 detects that the value of C in C register 22 is greater than P_{LL}=(Q/2+ 1/16), interval locator 40 decodes a LPS followed by an MPS and sends a signal decoding circuit 32_{C} to propagate the values of C and A generated according to set (3). Else, if the value of C in C register 22 is greater than P_{LL}=(Q/2+ 1/16) and interval locator 40 detects that the value of C in C register 22 is greater than or equal to 0, interval locator 40 decodes an LPS followed by and LPS and sends a signal decoding circuit 32_{C} to propagate the values of C and A generated according to set (4).

Because the QL-encoders and QL-decoders assume that A is close to one, a normalization circuit 35 renormalizes A and C when A drops below 0.75. To renormalize A and C, QL-encoders and QL-decoders may multiply A by two (i.e., shift left once) until A is greater than 0.75.

A binary arithmetic encoding system, such as the one described above, that looks at two symbols at a time is more efficient than a binary arithmetic encoding system that looks at one symbol at a time. In other words, running a 2-symbol QL-encoder is slightly faster than running a 1-symbol Q-coder twice. In a 2-symbol QL-encoder, Q may be updated block by block. Because Q is fixed for each block of data and QL-encoder re-computes Q after each block, the critical path is the calculation of values of C and A. Calculation of values of C and A requires time=2Tₐ, where Tₐ represents the time required for an add operation and multiplexing and shifting delays are ignored. 2Tₐ is equivalent to performance of a non-parallelized Q-coder run twice. Thus, a Q-coder with two regions of Q accomplishes twice amount of work can be done in one clock cycle. However, a 1-symbol Q-coder must access registers once per cycle and may have to renormalize more frequently. Thus, a 2-symbol QL-coder may be more efficient than a 1-symbol Q-coder.

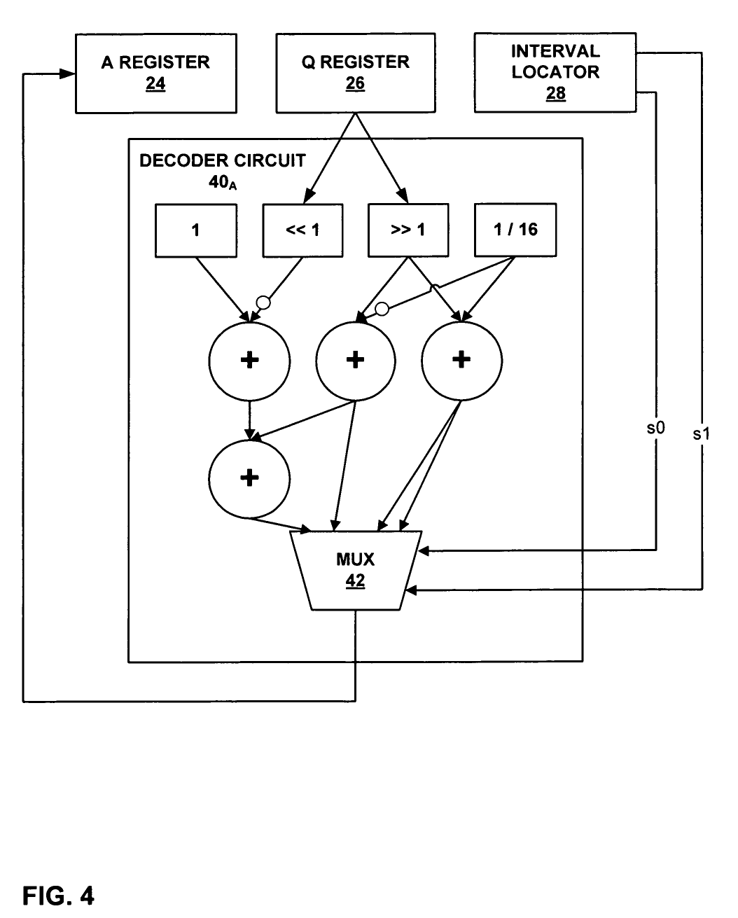

FIG. 4 is a block diagram illustrating an exemplary embodiment of a decoding circuit 40_{A} for a 2-symbol QL-decoder that generates values of A. When the QL-decoder receives an encoded message from a QL-encoder, decoding circuit 40_{A} calculates the following values of A in parallel:
A←−3Q/2+ 15/16 (1)
A←−Q/2+ 1/16 (2)
A←−Q/2+ 1/16 (3)
A←Q/2− 1/16 (4)

Each of these values of A represents a linear approximation of an interval corresponding to a two-symbol segment of an encoded version of data 12. Interval locator 28 of the QL-decoder sends signals s0 and s1 to a multiplexer 40 in decoding circuit 40_{A}. Signals s0 and s1 indicate to multiplexer 40 which of values (1) through (4) to propagate to A register 24.

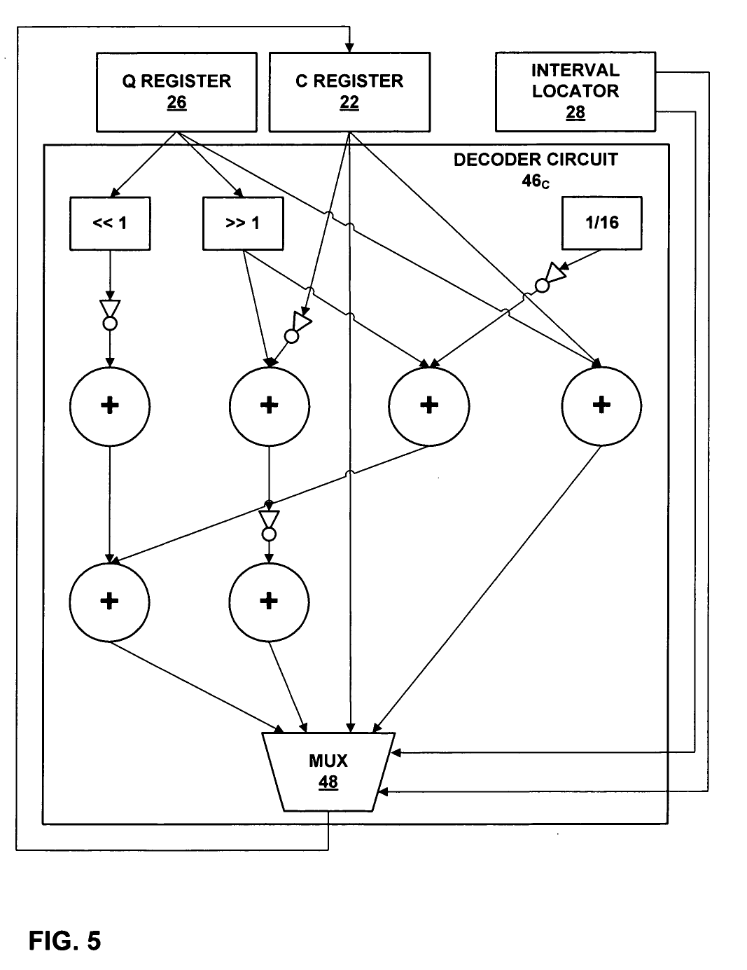

FIG. 5 is a block diagram illustrating an exemplary embodiment of a decoding circuit 46_{C} for a 2-symbol QL-decoder that generates values of C. When the 2-symbol QL-decoder receives an encoded block from a QL-encoder, such as QL-encoder 20 (FIG. 3), the decoding circuit 46_{C} calculates the following values of C in parallel:
C←C−3Q/2+ 1/16 (1)
C←C−Q+⅛ (2)
C←C−Q/2+ 1/16 (3)
C←C−0=C (4)

Each of these values of C represents a linear approximation of a location within the interval described by the current value of A in A register 24 for a two-symbol segment of an encoded block. Interval locator 28 of the QL-decoder sends signals s0 and s1 to a multiplexer 48 in decoding circuit 46_{C}. Signals s0 and s1 indicate to multiplexer 46 which of values (1) through (4) to propagate to C register 22.

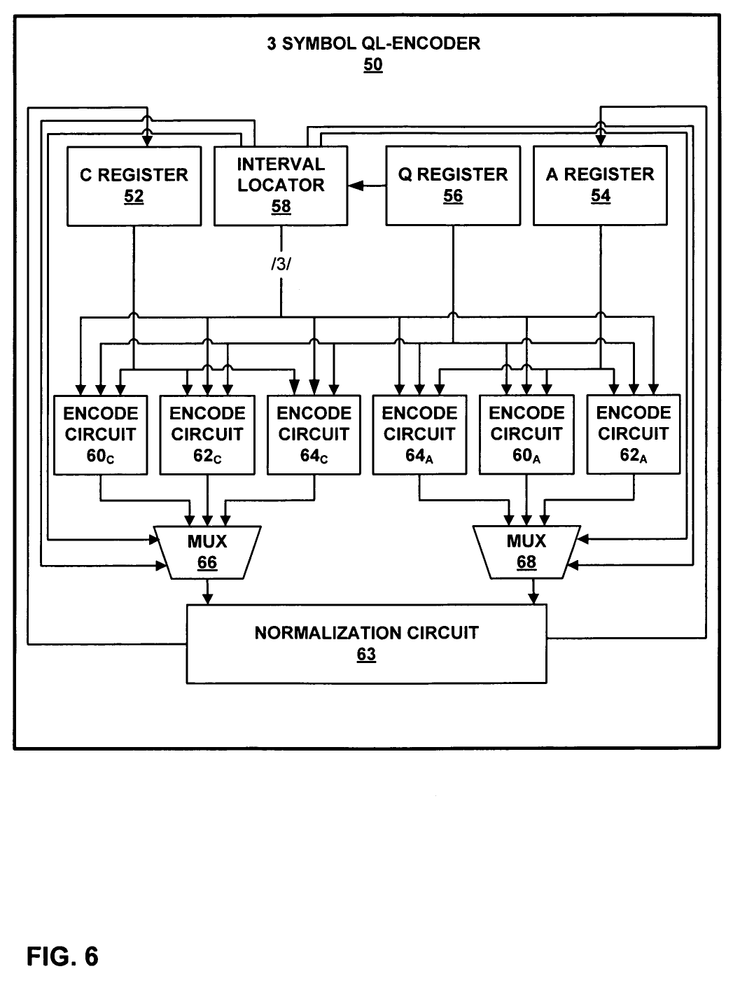

FIG. 6 is a block diagram illustrating an exemplary embodiment of a 3-region QL-encoder 50. Like QL-encoder 20, 3-region QL-encoder 50 includes a C register 52, an A register 54, a Q register 56, and an interval locator 58. Unlike 2-region QL-coder 20, 3-region QL-coder 50 a first set of encoding circuits 60, a second set of encoding circuits 62, and a third set of encoding circuits 64. Because 3-region QL-coder 50 contains three sets of encoding circuits, 3-region QL-coder 50 may generate three sets of C and A values for different expected values of Q. For instance, encoding circuits 60 may calculate values of C and A where the expected value of Q is near 0, encoding circuits 62 may calculate values of C and A where the expected value of Q is near ¼, and encoding circuits 62 may calculate values of C and A where the expected value of Q is near ½.

When QL-encoder 60 processes three symbols in parallel, there is an interval with interval A for each combination of three symbols. That is, there is an interval for
P_{LLL}=Q³
P_{LLM}=Q²*(1−Q)
P_{LML}=Q²*(1−Q)
P_{MLL}=Q²*(1−Q)
P_{MML}=Q*(1−Q)²
P_{MLM}=Q*(1−Q)²
P_{LMM}=Q*(1−Q)²
P_{MMM}=(1−Q)³

A linear approximation may be derived based on each of these probabilities. For example, encoding circuit 60_{C} may calculate the following values for C based on the linear approximations where the expected value of Q is 0 and m is a very small number:
P_{MMM}:C=C+3Q−5m
P_{MML}:C=C+2Q−2m
P_{MLM}:C=C+Q+m
P_{MLL}:C=C+Q
P_{LMM}:C=C+3m
P_{LML}:C=C+2m
P_{LLM}:C=C+m
P_{LLL}:C=C+0

Similarly, encoding circuit 62_{C} may calculate the following values for C based on the linear approximation where the expected value of Q is ¼:
P_{MMM}:C=C+27Q/16+ 10/64=>C+28Q/16+ 9/64
P_{MML}:C=C+25Q/16+ 2/64=>C+24Q/16+ 3/64
P_{MLM}:C=C+22Q/16− 3/64=>C+24Q/16− 5/64
P_{MLL}:C=C+17Q/16− 1/64
P_{MLL}:C=C+17Q/16− 1/64
P_{LMM}:C=C+14Q/16− 6/64
P_{LML}:C=C+9Q/16− 4/64
P_{LLM}:C=C+4Q/16− 2/64
P_{LLL}:C=C+0

Note that the coefficient of Q and the fraction in P_{MMM}, P_{MML}, P_{MLM} are changed in encoding circuit 62_{C}. This is because 27Q/16+ 10/64, 25Q/16+ 2/64, and 22Q/16− 3/64 cannot be calculated in time 2*Tₐ, where Tₐ is the time QL-encoder 50 takes to perform an addition. For this reason, the numbers have been altered to make a fair approximation. For example, encoding circuit 62_{C} may calculate 28Q/16+ 9/64 instead of 27Q/16+ 10/64. Encoding circuit 62_{C} may thus sacrifice some compression performance for the sake of processing performance.

Encoding circuit 64_{C} may calculate the following values for C based on the linear approximation where the expected value of Q is ½:
P_{MMM}:C=C+3Q/4+½
P_{MML}:C=C+Q+¼
P_{MLM}:C=C+5Q/4
P_{MLL}:C=C+Q
P_{LMM}:C=C+5Q/4−¼
P_{LML}:C=C+Q−¼
P_{LLM}:C=C+3Q/4−¼
P_{LLL}:C=C+0

Because the QL-encoders and QL-decoders assume that A is close to one, a normalization circuit 63 renormalizes A and C when A drops below 0.75. To renormalize A and C, QL-encoders and QL-decoders may multiply A by two (i.e., shift left once) until A is greater than 0.75.

A 3-region QL-decoder may share a similar architecture to QL-encoder 50. However, as described below, the operation of interval 58 is different. In addition, in a 3-region QL-decoder, encoding circuits 60, 62, and 64 are replaced with decoding circuits 60, 62, and 64. Decoding circuits 60, 62, and 64 use the same linear approximations as their counterparts in QL-encoder 50. However, decoding circuits 60, 62, and 64 reverse the encoding process performed by decoding circuits in QL-encoder 50. For example, decoding circuit 60_{A} may calculate the following values of A based on a linear approximation where the expected value of Q is 0:
P(3M,0L):A=(1−Q)³≈3Q+1≈−3Q+1
P(2M,1L):A=(1−Q)²Q≈Q≈Q−3m
P(1M,2L):A(1−Q)Q²≈0
P(0M,3L):A=Q³≈0

Because [−3Q+1]+3[Q]+3[0]+[0]=1, the values of A produced by decoding circuit 60_{A} are valid in the region where 0≦Q≦⅙.

Decoding circuit 62_{A} may calculate the following values of A based on the linear approximation where the expected value of Q is ¼:
P(3M,0L):A=(1−Q)³≈27Q/16+ 54/64≈28Q/16+ 57/64≧0
P(2M,1L):A=(1−Q)²Q≈3Q/16+ 6/64≈3Q/16+ 5/64≧0
P(1M,2L):A=(1−Q)Q²≈5Q/16− 2/64≧0
P(0M,3L):A=Q³≈3Q/16− 2/64≈4Q/16− 2/64≧0

Because

[−28Q/16+ 57/64]+3[3Q/16+ 5/64]+3[5Q/16− 2/64]+[4Q/16− 2/64]=1, the values of A produced by decoding circuit 62_{A} are valid in the region where ⅙≧Q≧⅓.

Circuit 64_{A} may calculate the following values for A based on the linear approximation where the expected value of Q is ½:
P(3M,0L):A=(1−Q)³≈−3Q/4+½≧0
P(2M,1L):A=(1−Q)²Q≈−Q/4+¼≧0
P(1M,2L):A=(1−Q)Q²≈Q/4≧0
P(0M,3L):A=Q³≈3Q/4−¼≧0

Because [−3Q/4+½]+3[−Q/4+¼]+3[Q/4]+[3Q/4−¼]=1, the values of A produced by decoding circuit 64_{A} are valid in the region where ⅓≦Q≦½. In decoding circuits 60_{A}, 62_{A}, and 64_{A}, each of the multiplications and divisions may be replaced with shifts and adds.

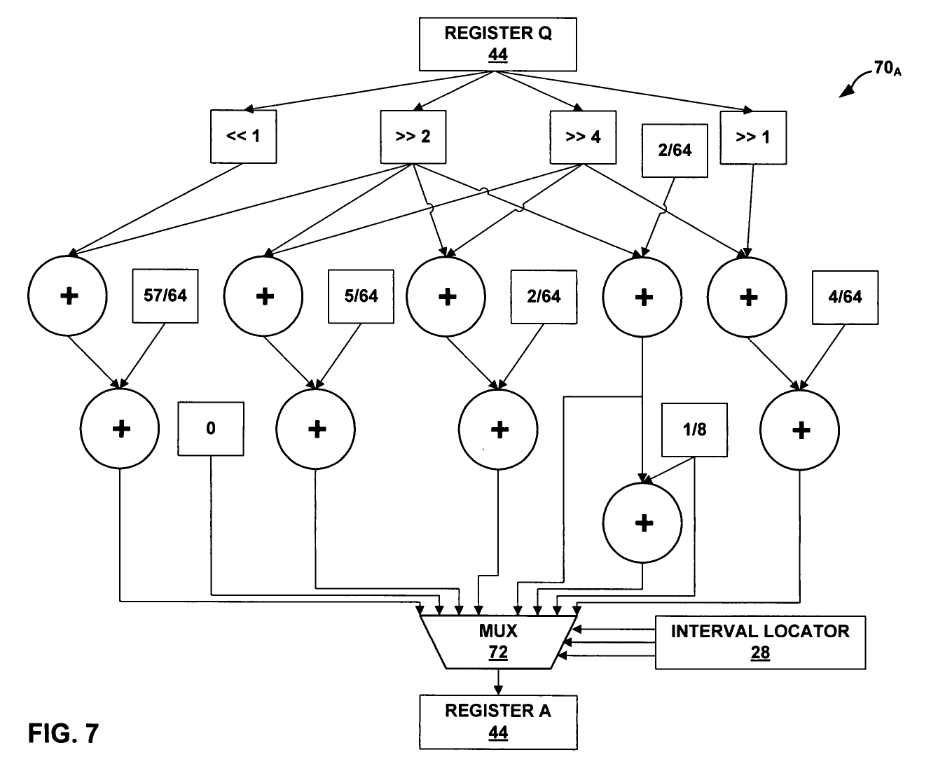

FIG. 7 is a block diagram illustrating an exemplary embodiment of a decoding circuit 70_{A} that processes for three symbols in parallel. As illustrated in FIG. 7, circuit 70_{A} calculates the following values of A in parallel:
P_{MMM}:A=(1−Q)³≈27Q/16+ 54/64≈28Q/16+ 57/64≧0
P_{LMM}:A=(1−Q)²Q≈3Q/16+ 6/64≈3Q/16+ 5/64≧0
P_{MLM}:A=(1−Q)²Q≈3Q/16+ 6/64≈3Q/16+ 5/64≧0
P_{MML}:A=(1−Q)²Q≈3Q/16+ 6/64≈3Q/16+ 5/64≧0
P_{MLL}:A=(1−Q)Q²≈5Q/16− 2/64≧0
P_{LML}:A=(1−Q)Q²≈5Q/16− 2/64≧0
P_{LLM}:A=(1−Q)Q²≈5Q/16− 2/64≧0
P_{LLL}:A=Q³≈3Q/16− 2/64≈4Q/16− 2/64≧0
After decoding circuit 70_{A} calculates each of these values of A, a multiplexer 72 selects one of the signals based on the values of the incoming symbols. For example, if QL-decoder 50 is decoding an LPS followed by an LPS followed by another LPS, multiplexer 72 propagates A=4Q/16− 2/64.

In general, a 3-symbol QL-decoder using decoding circuit 70_{A} may be 1.5 times faster than a 1 symbol binary arithmetic coder. Because addition is the most expensive operation in and a 3-symbol QL-coder may use up to two additions, the most time-consuming path is 2*Tₐ (with some approximation and precision loss for this). However, a 3-symbol QL-coder processes three symbols in parallel. Thus, when the register setup/hold time and normalization time are ignored, the time to process three symbols with a 3-symbol QL coder is essentially 2*Tₐ. In contrast, the time to process three symbols with a 1-symbol Q-coder is essentially 3*Tₐ. Therefore, the performance ratio of a 1-symbol Q-coder to a 3-symbol QL coder is 3:2. In other words, the 3-symbol QL-coder is 1.5 times faster than a 1-symbol Q-coder. This performance ratio may be greater because a 1-symbol Q-coder access incurs three register setup/hold times and normalization times for each symbol.

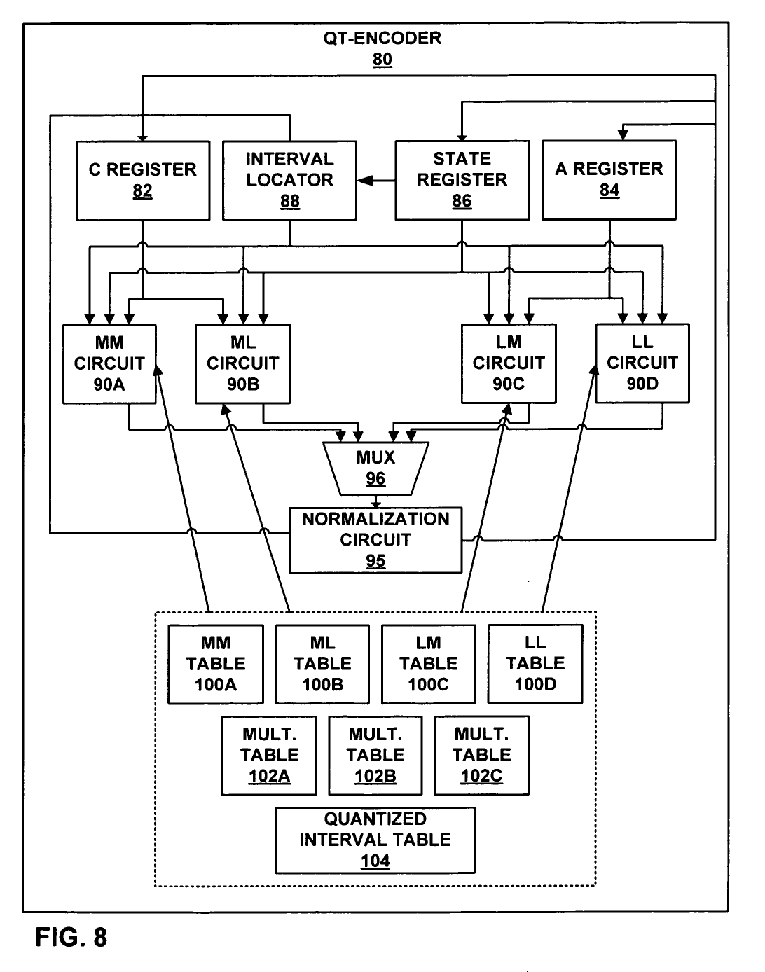

FIG. 8 is a block diagram illustrating a binary arithmetic encoder that uses a table look-up mechanism to process two symbols in parallel. Because this binary arithmetic coder uses a table look-up mechanism, the binary arithmetic coder may act as an improvement of a serial version CABAC in H.264. Because this binary arithmetic encoder uses a table look-up mechanism, the binary arithmetic encoder is referred to herein as a Q-table (QT) coder 80.

QT-encoder 80 includes a C register 82, a state register 86, and an A register 84. Unlike the QL-coders described above, the value of Q in the QT-encoder 80 is not fixed within a set of data to be encoded or decoded in parallel. Rather, the value of Q changes whenever a symbol encoded, or in the case of a QT-decoder, whenever a symbol is decoded. Thus, if QT-encoder 80 encodes a LPS, the value of Q may increase to Q2′ and if a MPS is received, the value of Q may decrease to Q2.

2-symbol QT-encoder 80 encodes two symbols in parallel. Because 2-symbol QT-encoder 80 encodes two symbols simultaneously, and the value of Q may change after QT-encoder 80 encodes each symbol, it is necessary to know the value of Q in the current state, the value of Q if the first symbol is a MPS, and the value of Q if the first symbol is a LPS. For this reason, QT-encoder 80 includes a MM table 100A, a ML table 100B, a LM table 100C, and a LL table 100D (collectively, state tables 100). MM table 100A is a mapping between a current value of Q and a value of Q after QT-encoder 80 encodes an MPS followed by another MPS. ML table 100B contains a mapping between a current value of Q and a value of Q after QT-encoder 80 encodes an MPS followed by an LPS. LM table 100C contains a mapping between a current value of Q and a value of Q after QT-encoder 80 receives an LPS followed by an MPS. Finally, LL table 100D contains a mapping between a current value of Q and a value of Q after QT-encoder 80 receives an LPS followed by an LPS.

Unlike the QL-coders described above, QT-encoder 80 does not assume that A is approximately equal to 1. To simplify calculations, QT-encoder 80 includes multiplication tables 102A through 102C (collectively, multiplication tables 102). Multiplication tables 102 contain a value for each combination of a value of Q and a quantized A value. In particular, for each value of Q in state tables 100 and value of quantized A, multiplication table 102A contains a value that corresponds to A*Q1+A*Q2−A*Q1*Q2, where Q1 is the current value of Q and Q2 is the value of Q after receiving an MPS. Multiplication table 102B contains values corresponding to A*Q1. Multiplication table 102C contains values corresponding to A*Q1*Q2′, where Q2′ is the value of Q after receiving an LPS. All the table lookup including multiplication tables and next state tables are looked up simultaneously in one clock cycle.

If 2-symbol QT-encoder 80 is an encoder, an MM circuit 90A performs the following operation:
C=C+(A*Q1+A*Q2−A*Q1*Q2)
A=A(1−Q1)(1−Q2)=A−(A*Q1+A*Q2−A*Q1*Q2)
state=mm_table(state)

An ML circuit 90B performs the operations:
C=C+(A*Q1)
A=A(1−Q1)Q2=AQ2−A*Q1*Q2=(AQ1+AQ2−AQ1Q2)−(AQ1)
state=ml_table(state)

An LM circuit 90C performs the operations:
C=C+(A*Q1*Q2′)
A=AQ1(A−Q2′)=(AQ1)−(AQ1Q2)
state=lm_table(state)

An LL circuit 90D performs to operations:
A=(A*Q*Q2)
state=ll_table(state)

All the above A and C values can be computed by one table lookup and one addition or subtraction, which means the updating of A and C are also done in parallel.

While encoding circuits 90 are performing these operations, a multiplexer 96 selects which set of results to propagate based on the input symbols. For example, if the input symbols are a LPS followed by a MPS, multiplexer 90 propagates the values of C, A, and state generated by LM circuit 90C. When multiplexer 90 receives the values of C, A, and state from encoding circuits 90, multiplexer 96 propagates the values of C and A and state the from the selected encoding circuit to C register 82, A register 84, and state register 86, respectively.

A QT-decoder may have a similar architecture to QT-encoder 80. However, a QT-decoder may include an interval locator 88. In addition, encoding circuits 90 of QT-encoder 80 are replaced with decoding circuits 90. MM decoding circuit 90A generates the following values:
C=C−(AQ1+AQ2−AQ1Q2)
A=A−(AQ1+AQ2−AQ1Q2)
state=mm_table(state)

ML decoding circuit 90B generates the following values:
C=C−(AQ1)
A=(AQ1+AQ2−AQ1Q2)−(AQ1)
state=ml_table(state)

LM decoding circuit 90C generates the following values:
C=C−(AQ1Q2′)
A=(AQ1)−(AQ1Q2′)
state=lm_table(state)

LL decoding circuit 90D generates the following values:
A=(AQ1Q2′)
state=ll_table(state)
S/W L/MPS

A normalization circuit 95 renormalizes A and C when A drops below 0.75. To renormalize A and C, QL-encoders and QL-decoders may multiply A by two (i.e., shift left once) until A is greater than 0.75.

While decoding circuits 90 are generating these values of C, A, and state, interval locator 110 determines which two-symbol sequence is being decoded. For instance, interval locator 110 may implement the following procedure:

```
if ( C ≧ ( AQ1 + AQ2 − AQ1Q2 ) ) {
    MM decoded
} else if ( C ≧ AQ1 ) {
    ML decoded
} else if ( C ≧ AQ1Q2′ ) {
    LM decoded
} else {
    LL decoded
}
```

After determining which two-symbol sequence is being decoded, interval locator 110 sends a signal to multiplexer 96 that indicates which set of updated values of C, A, and state to use. For example, if interval locator 110 determines that the C≧(A*Q1+A*Q2−A*Q1*Q2), interval locator 110 sends a signal to multiplexer 96 that indicates that multiplexer 96 should propagate the values of C, A, and state from MM circuit 90A but not the values from ML circuit 90B, LM circuit 90C, or LL circuit 90D.

The compression ratio of a 2-symbol QT-encoder/decoder is similar to the compression ratio of a 1-symbol QT-encoder/decoder. However, a 2-symbol QT-encoder/decoder handles twice as many symbols in a given clock cycle. In other words, the total time to process two symbols in a 2-symbol QT-encoder/decoder is Tₜₒₜₐₗ′=(T_{table}+Tₐ+Tₙ+Tₛₕ), where T_{table} is the time to look up a value in a table, Tₐ is the time to perform an addition, Tₙ is the normalization time, and Tₛₕ is the time to set and hold a register. In contrast, the total time to process two symbols in a 1-symbol QT encoder/decoder is Tₜₒₜₐₗ=2*(T_{table}+Tₐ+Tₙ+Tₛₕ)

The price paid for the higher speed is more memory for an additional table and the extra circuitry to handle the additional table. To keep the critical path constant, the total number of state tables and multiplication tables increases exponentially. For example, when a QT-coder processes three symbols in parallel, the QT-coder may require eight state tables and seven multiplication tables. A QT-coder processes four symbols in parallel, the QT-coder may require sixteen state tables and fifteen multiplication tables. To reduce the total memory usage, more quantization steps may be required. However, this may degrade the compression ratio and the total computation time may be greater than 2*T_{A}.

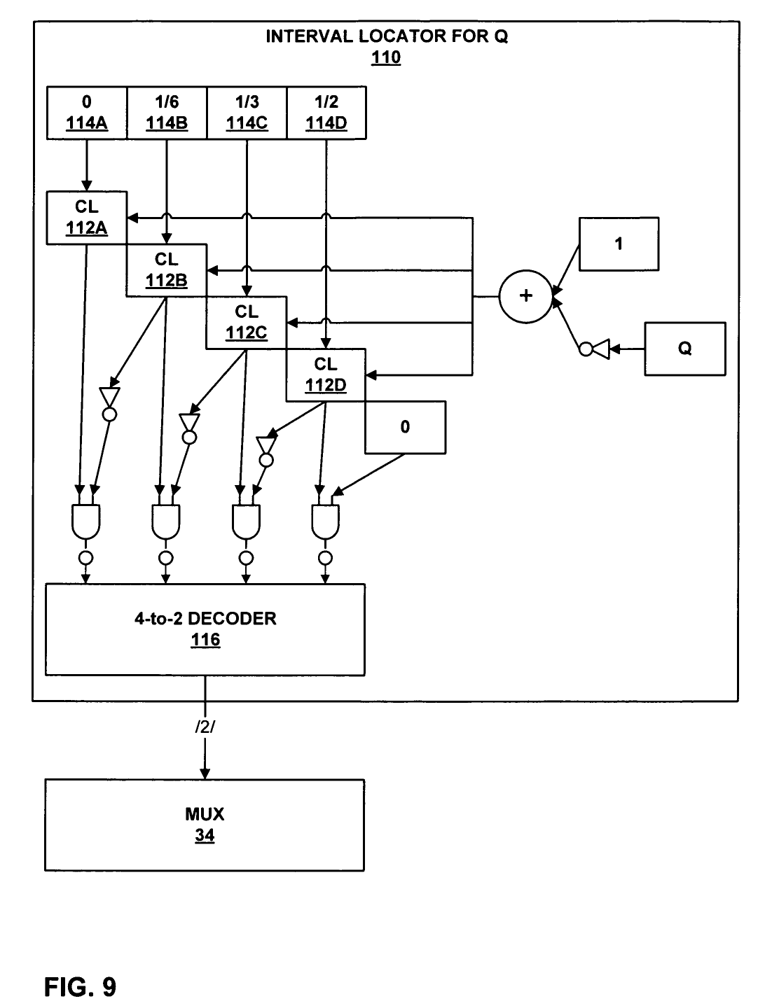

FIG. 9 is a block diagram illustrating an exemplary interval locator 110 that selects a set of C and A values given a value of Q. Interval locator 110 may be interval locator 58 in QL-encoder 50 (FIG. 6), a QL-decoder counterpart to QL-encoder 50, or otherwise. As described below, interval locator 110 performs a single addition operation. For this reason, interval locator 10 does not degrade the performance of QL-encoder 50 below 2*Tₐ.

Interval locator 110 includes sign bit identifiers 112A through 112D (collectively, sign bit identifiers 112). Each of sign bit identifiers 112 may be a sign bit of a carry look-ahead adder. Thus, if an addition between the inputs of one of sign bit identifiers 112 would result in a positive number, the sign bit identifier outputs a zero. In contrast, if an addition between the inputs of a sign bit identifier would produce a negative number, the sign bit identifier outputs a one. Because sign bit identifiers 112 do not perform a full addition, sign bit identifiers 112 may be significantly faster than a full adder.

Interval locator 110 also includes interval registers 114A through 114D (collectively, interval registers 114). Interval registers 114 contain endpoints of regions of Q. For instance, suppose a QL-coder includes a first region of Q that is valid when 0≦Q≦⅙, a second region of Q that is value when ⅙≦Q<⅓, and a third region of Q that is valid when ⅓≦Q<½. In this situation, interval register 114A may contain the value 0, interval register 114B may contain the value ⅙, interval register 114C may contain the value ⅓, and interval register 114 may contain the value ½.

To identify a region of Q, interval locator 110 inverts the value of Q. That is, each 0 bit of Q is transformed into a 1 and each 0 bit of Q is transformed into a 1. Interval locator 110 then supplies the inverted value of Q to sign bit identifiers 112 as an input. Each of sign bit identifiers 112 determines whether a potential addition between the result of the subtraction and a corresponding one of interval registers 114 would produce a positive or negative number. Sign bit identifiers 112 then send the sign bits through combinations of AND gates. Based on the pattern of outputs from these AND gates, a 4-to-2 decoder 116 translates the four inputs into two output signals. 4-to-2 decoder 116 then propagates these signals a multiplexer such as multiplexers 66 and 68 in FIG. 6.

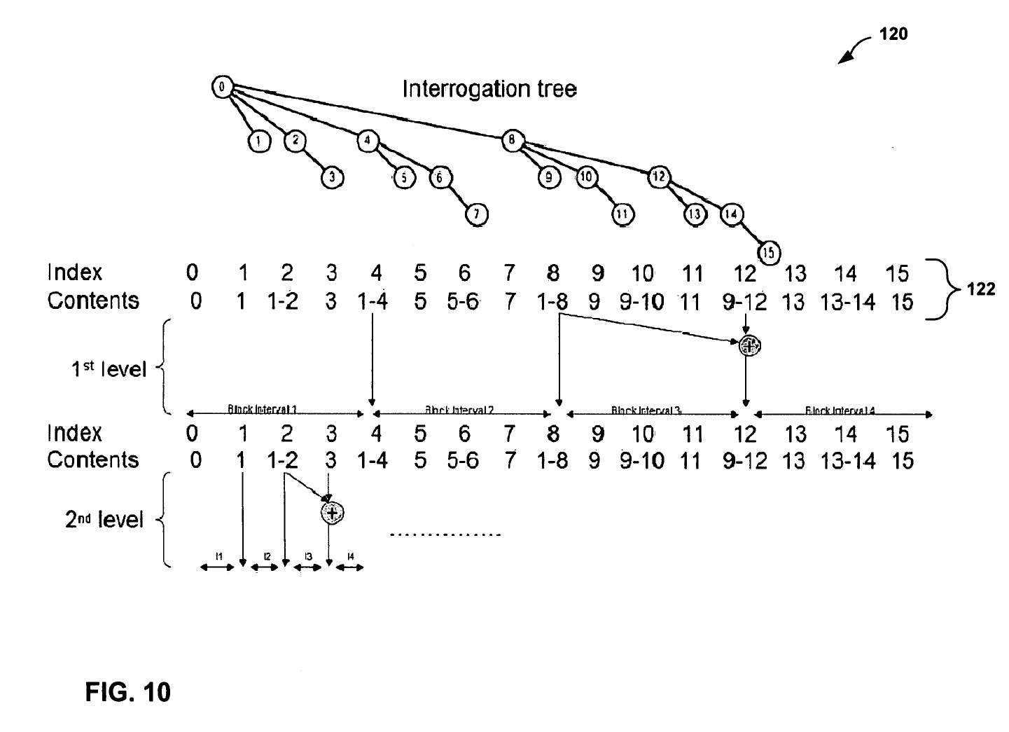

FIG. 10 is a block diagram illustrating an exemplary data structure 120 may be used in a decoding interval locator. For instance, data structure 120 may serve as the basis for a decoding portion of interval locator in the decoding counterpart of QL-coder 50 in FIG. 6.

Instead of storing the probabilities of each combination of symbols to be decoded, data structure 120 stores partial sums of some probabilities in a single array 122. As represented in FIG. 10, entries in an upper row of array 122 are register numbers and entries in a lower row of array 122 are partial sum of probabilities.

Recall that Cᵢ₊1=Cᵢ+Aᵢ*Sᵢ(k) and that Sᵢ is the cumulative probability of symbol k. In other words, S(k)=ΣP(j) for j=1 to k−1. In terms of FIG. 2, the cumulative probability of an MPS followed by an MPS k=4 and S(k)=ΣP(j) equals Q+(Q−Q²)+(Q−Q²).

By accessing registers 4 and 8 in array 112, an interval locator may obtain S(k)=ΣP(j) for P(1)+P(2)+ . . . P(4) and P(1)+P(2)+ . . . P(8) without using an adder. By using a single adder on the values of register 4 and register 8, an interval locator may obtain S(k)=ΣP(j) for P(1)+P(2)+ . . . P(12). This allows the interval locator to determine whether C is in the intervals of probabilities contained in registers 0 and 4, registers 4 and 8, registers 8 and 12, or registers 12 and 15.

After identifying which range of registers C is in, the interval locator accesses registers of array 112 within the identified range. For example, if the interval locator determines that C is somewhere between register 0 and register 4, the interval locator accesses registers 0 through 3. In this way, the interval locator may obtain S(k)=ΣP(j) for P(1) and P(1)+P(2) without using an adder. By using a single adder on the values of register 2 and register 3, the interval locator may obtain S(k)=ΣP(j) for P(1) through P(3). In this way, the interval locator may obtain S(k)=ΣP(j) for every four symbol combination while only using two addition operations. Because the interval locator only uses two addition operations, the 2*Tₐ performance standard of QL-decoder is maintained.

An updating tree may be used to update the partial probabilities in array 112. In the updating tree, if any non-root register is updated, then its parent must also be updated. The interval locator may use an interrogation tree to obtain the cumulative probability quickly.

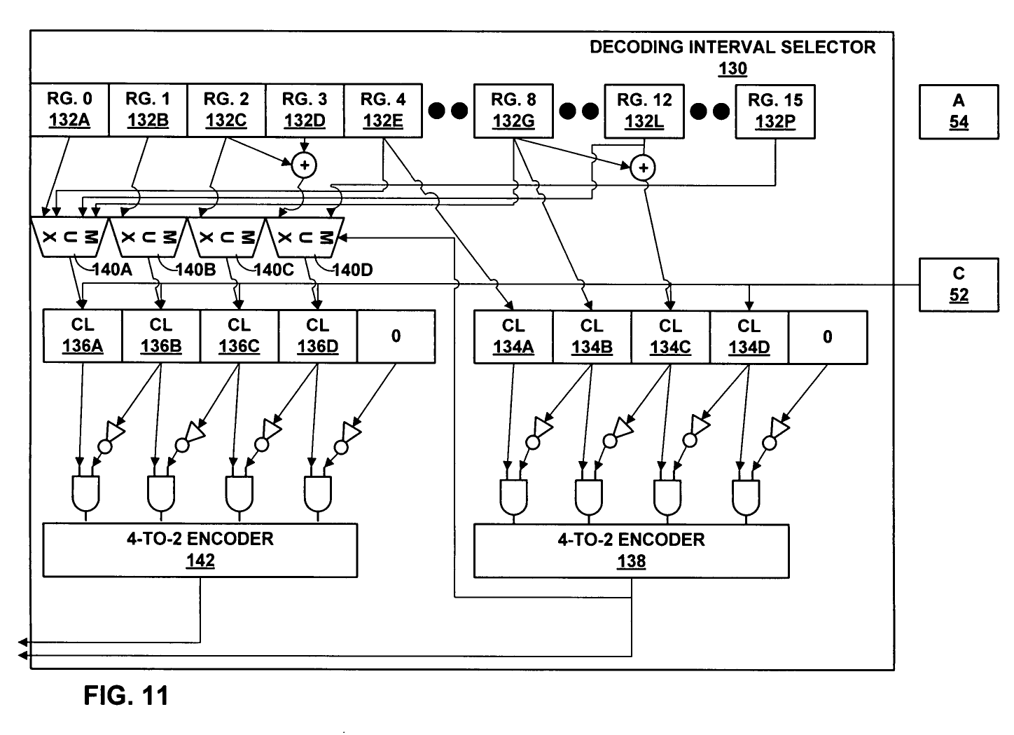

FIG. 11 is a block diagram illustrating an exemplary embodiment of an interval locator 130 based on the cumulative probability array data structure of FIG. 10. Interval locator 130 may be used in a parallel binary arithmetic decoding process. Interval locator 130 is appropriate for a 4-symbol QL-decoder. Because the QL-decoder looks at four symbols in parallel, interval locator 130 determines which of sixteen intervals C is in. In FIG. 11, CL means the Carry-Look-Ahead part of an adder.

In interval locator 130, CL circuits 134A through 134D (collectively, CL circuits 134) quickly obtain the sign bits of potential additions between C and the cumulative probability values of registers 4 (132D), 8 (132G), the sum of registers 4 (132D) and 8 (132G), and the value of A register 54. The resulting output of the CL circuits 134 is a code (e.g., [1 1 0 0]). A 4-to-2 encoder 138 can then convert this code into signals that identifies to a series of multiplexers 140A through 140D (collectively, multiplexers 140) whether C is located between register 0 and register 4, between register 4 and register 8, between register 8 and register 12, or register 12 and register 15. Although not shown the signals from 4-to-2 encoder 138 reach each of multiplexers 140. For example, if C is located between register 0 and register 4, 4-to-2 encoder 138 may output 00; if C is between registers 4 and 8, 4-to-2 encoder 138 may output 01. This two-signal code from 4-to-2 encoder 138 may also act as the more significant signals to multiplexers in decoding circuits.

Multiplexers 140 propagate the values of a range of C to CL circuits 136A through 136D (collectively, CL circuits 136). For instance if 4-to-2 encoder 138 sends signal 00 to multiplexers 140, multiplexers 140 propagate values from registers 0 (132A) through 3 (132D) to CL circuits 136. CL circuits 136 obtain the sign bits of potential additions between C and the cumulative probability values of registers values. CL circuits 136 then output the sign bits to a combination of AND gates. These AND gates output a code to a 4-to-2 encoder 142. The 4-to-2 encoder 142 converts the outputs of the AND gates into a two signal code. The two-signal code from 4-to-2 encoder 142 is subsequently added as the less significant signals to multiplexers in decoding circuits.

Usually the probability is obtained from dividing the frequency count of that simple by the total count. If integer division is used to obtain the probability, then computation may be slow. The division operation can be replaced by a shift operation. This is possible by setting the denominator equal to 256, if it is the buffer size (or a multiple of it) for context based coding. The previous 256 (or say, 32) en/de-coded symbols have to be kept in the FIFO buffer. When the oldest symbol is removed, the corresponding registers can be decremented (or −8) quickly to undo its effect on the statistical model, since they are either too old or no longer important (for example it may no longer be the neighbors of current processing pixel). Every time a new symbol is received its corresponding register is incremented (+8) and the oldest symbol's corresponding register is decremented (−8). Therefore, the denominator will always be the same (256). Specific data can be loaded into the FIFO buffer initially. This buffer helps increase the compression ratio because the buffer provides a more accurate and significant model.

Various embodiments of the invention have been described. These and other embodiments are within the scope of the following claims.

1. A method comprising:
receiving a stream of binary data symbols; and
applying a parallel binary arithmetic coding scheme to a set of the data symbols to simultaneously encode the set of data symbols,
wherein the set of data symbols includes more probable binary symbols (MPSs) and less probable binary symbols (LPSs).

2. The method of claim 1, further comprising updating and normalizing an interval register and a code register for every set of the data symbols.

3. The method of claim 1, wherein the parallel binary arithmetic coding scheme simultaneously encodes the set of data symbols based on a probability of receiving a less probable symbol.

4. The method of claim 1, wherein the stream of data symbols comprise a stream of video data symbols.

5. The method of claim 1, wherein the parallel binary arithmetic coding scheme comprises an L-level parallel binary arithmetic coding scheme that includes 2^{L} probability states.

6. The method of claim 1, wherein applying the parallel binary arithmetic coding scheme comprises applying a linear approximation to probabilities of the set of data symbols.

7. The method of claim 6, further comprising assuming that the probability of receiving a less probable symbol is substantially constant.

8. The method of claim 1, wherein applying the parallel binary arithmetic coding scheme comprises applying look-up tables for the set of data symbols.

9. The method of claim 8, wherein the parallel binary arithmetic coding scheme comprises an L-level parallel binary arithmetic coding scheme.

10. The method of claim 9, wherein the look-up tables include 2^{L} next state look-up tables and 2^{L}−1 multiplication look-up tables.

11. The method of claim 9, further comprising:
increasing the probability of receiving a less probable symbol when a less probable symbol is received; and
decreasing the probability of receiving a less probable symbol when a more probable symbol is received.

12. The method of claim 1, wherein the set of data symbols comprises at least three binary symbols.

13. The method of claim 1, further comprising locating a specific interval of the encoded set of data symbols using an interval locator that simultaneously traverses all probability states of the parallel binary arithmetic coding scheme.

14. The method of claim 1, further comprising applying the parallel binary arithmetic coding scheme to the encoded set of the data symbols to simultaneously decode the set of data symbols.

15. The method of claim 1, wherein the application of the parallel binary arithmetic coding scheme to each data symbol in the set of data symbols is completed within a fixed number of clock cycles.

16. The method of claim 15, wherein the fixed number of clock cycles is substantially equal to twice the number of clock cycles required to perform an addition operation.

17. A computer-readable medium comprising instructions that cause a processor to:
receive a stream of binary data symbols; and
apply a parallel binary arithmetic coding scheme to a set of the data symbols to simultaneously encode the set of data symbols,
wherein the set of data symbols includes more probable binary symbols and less probable binary symbols.

18. The computer-readable medium of claim 17, wherein the parallel binary arithmetic coding scheme comprises an L-level parallel binary arithmetic coding scheme that includes 2^{L} probability states.

19. The computer-readable medium of claim 17, wherein the instructions cause the processor to apply the parallel binary arithmetic coding scheme cause the processor to apply a linear approximation for the set of data symbols.

20. The computer-readable medium of claim 17, wherein the instructions cause the processor to apply the parallel binary arithmetic coding scheme cause the processor to apply look-up tables for the set of data symbols.

21. The computer-readable medium of claim 17, wherein the instructions cause the processor to complete the application of the parallel binary arithmetic coding scheme to each data symbol in the set of data symbols within a fixed number of clock cycles.

22. An electronic device comprising:
an encoder to encode a set of data symbols in a stream of binary data symbols,
wherein the encoder applies a parallel binary arithmetic coding scheme to encode all of the data symbols of the set of binary data symbols in parallel,
wherein the set of data symbols includes more probable binary symbols and less probable binary symbols.

23. The electronic device of claim 22, wherein the encoder comprises a set of encoding circuits to apply the parallel binary arithmetic coding scheme by applying a first order linear approximation to a probability of the set of binary data symbols.

24. The electronic device of claim 23,
wherein the encoder applies the parallel binary arithmetic coding scheme by generating n sets of results by applying n linear approximations for n regions of a probability of decoding a binary symbol, where n is an integer greater than 1; and
wherein the encoder further comprises an interval locator to select a result from the sets of results based on a probability of the binary symbol.

25. The electronic device of claim 23, wherein the set of binary data symbols comprises at least three symbols.

26. The electronic device of claim 22, wherein the encoder applies the parallel binary arithmetic coding scheme by applying look-up tables to the set of data symbols.

27. The electronic device of claim 26, wherein the encoder increases the probability of receiving a less probable symbol when a less probable symbol is received and decreases the probability of receiving a less probable symbol when a more probable symbol is received.

28. The electronic device of claim 26, wherein the set of binary data symbols is greater than or equal to two.

29. The electronic device of claim 22, wherein the encoder completes the application of the parallel binary arithmetic coding scheme to each data symbol in the set of data symbols within a fixed number of clock cycles.

30. An electronic device comprising:
a decoder to decode a set of data symbols in a stream of binary data symbols,
wherein the decoder applies a parallel binary arithmetic coding scheme to decode all of the data symbols of the set of binary data symbols in parallel,
wherein the set of data symbols includes more probable binary symbols and less probable binary symbols.

31. The electronic device of claim 30, wherein the decoder comprises a set of decoding circuits to apply the parallel binary arithmetic coding scheme by applying a first order linear approximation to a probability of the set of binary data symbols.

32. The electronic device of claim 31, wherein the set of binary data symbols comprises at least three symbols.

33. The electronic device of claim 31,
wherein the decoder applies the parallel binary arithmetic coding scheme by generating n sets of results by applying n linear approximations for n regions of a probability of decoding a binary symbol, where n is an integer greater than 1; and
wherein the decoder further comprises an interval locator to select a result from the sets of results based on a probability of the binary symbol.

34. The electronic device of claim 30, wherein the decoder applies the parallel binary arithmetic coding scheme by applying look-up tables for the set of data symbols.

35. The electronic device of claim 34, wherein the set of binary data symbols comprises at least two symbols.

36. The electronic device of claim 34, wherein the decoder increases the probability of receiving a less probable symbol when a less probable symbol is received and decreases the probability of receiving a less probable symbol when a more probable symbol is received.

37. The electronic device of claim 30, wherein the decoder completes the application of the parallel binary arithmetic coding scheme to each data symbol in the set of data symbols within a fixed number of clock cycles.

38. A system comprising:
a first communication device comprising:
an encoder to encode a set of data symbols in a stream of binary data symbols,
wherein the encoder applies a parallel binary arithmetic coding scheme to encode all of the data symbols of the set of binary data symbols in parallel,
wherein the set of data symbols includes more probable binary symbols and less probable binary symbols; and
a second communication device comprising:
a decoder to decode the set of data symbols,
wherein the decoder applies the parallel binary arithmetic coding scheme to decode all of the data symbols of the set of binary data symbols in parallel.

39. The electronic device of claim 38, wherein the encoder and decoder complete the application of the parallel binary arithmetic coding scheme to each data symbol in the set of data symbols within a fixed number of clock cycles.
